(19) United States
(12) Patent Application Publication
(10) Pub. No.: US 2024/0272235 A1
(43) Pub. Date: Aug. 15, 2024

(54) BATTERY DIAGNOSTIC SYSTEM

(71) Applicant: DENSO CORPORATION, Kariya-city (JP)

(72) Inventors: Yuta SHIMONISHI, Kariya-city (JP); Shuhei Yoshida, Kariya-city (JP)

(21) Appl. No.: 18/646,120

(22) Filed: Apr. 25, 2024

Related U.S. Application Data
(63) Continuation of application No. PCT/JP2022/041695, filed on Nov. 9, 2022.

(30) Foreign Application Priority Data
Dec. 28, 2021 (JP) 2021-214442

(51) Int. Cl. G01R 31/392; G01N 27/02; G01R 31/367; G01R 31/389; G01R 31/396

(52) U.S. Cl. CPC G01R 31/392; G01N 27/026; G01R 31/367; G01R 31/389; G01R 31/396

(57) ABSTRACT

A battery diagnostic system that estimates SOH indicating a degree of deterioration of a secondary battery includes a model section, a SOH calculation section, and a SOH estimation section. The model section acquires usage history data indicating an usage state of the secondary battery, and calculates the SOH based on the usage history data. The SOH calculation section acquires physical quantities that change depending on the degree of deterioration of the secondary battery as sensing data, and calculates the SOH based on the sensing data. Based on the SOH calculated by the model section and the SOH calculated by the SOH calculation section, the SOH estimation section combines both calculation results to estimate an optimal SOH.

### CROSS REFERENCE TO RELATED APPLICATIONS

This application is a continuation application of International Patent Application No. PCT/JP2022/041695 filed on Nov. 9, 2022, which designated the U.S. and based on and claims the benefits of priority of Japanese Patent Application No. 2021-214442 filed on Dec. 28, 2021. The entire disclosure of all of the above applications is incorporated herein by reference.

### TECHNICAL FIELD

The present disclosure relates to a battery diagnostic system.

### BACKGROUND

Conventionally, a method for diagnosing a remaining life of a secondary battery module is proposed.

### SUMMARY

The present disclosure aims to provide a battery diagnostic system that can improve the accuracy of estimating the SOH of a secondary battery.

According to the first and second aspects of the present disclosure, the battery diagnostic system estimates the SOH that indicates the degree of deterioration of the secondary battery.

In a first aspect, a battery diagnostic system includes a model section, a SOH calculation section, and a SOH estimation section.

The model section acquires usage history data indicating an usage state of the secondary battery, and calculates the SOH based on the usage history data. The SOH calculation section acquires physical quantities that change depending on the degree of deterioration of the secondary battery as sensing data, and calculates the SOH based on the sensing data. Based on the SOH calculated by the model section and the SOH calculated by the SOH calculation section, the SOH estimation section combines both calculation results to estimate an optimal SOH.

In a second aspect, the battery diagnostic system includes a data acquisition unit, a data processing unit, and a calculation unit.

The data acquisition unit acquires time-series data indicating the usage state of the secondary battery. The data processing unit acquires time series data from the data acquisition unit and processes the time series data as histogram data.

The calculation unit calculates the SOH as an estimated value using either the time series data acquired by the data acquisition unit or the histogram data acquired by the data processing unit based on a preset calculation model.

### BRIEF DESCRIPTION OF THE DRAWINGS

The above and other objects, features and advantages of the present disclosure will be more clearly understood from the following detailed description with reference to the accompanying drawings. In the drawings:

FIG. 1 is a diagram showing a configuration of a battery diagnostic system according to a first embodiment;

FIG. 2 is a diagram showing preprocessing to obtain a specific frequency in advance, and processing to calculate SOH using the specific frequency;

FIG. 3 is a diagram showing a correlation between a relationship between an imaginary component Zimage of impedance and SOH, and frequency;

FIG. 4 is a diagram showing specific frequencies with respect to a number of dimensions;

FIG. 5 is a diagram showing each error of learning data, cross-validation data, and verification data for each number of dimensions;

FIG. 6 is a diagram in which a real component Zreal and an imaginary component Zimage of the impedance measured by an impedance generator are plotted for each frequency;

FIG. 7 is a diagram showing an estimated value of SOH by a SOH calculation section and an actual measured value of SOH when a temperature of the secondary battery is 45° C. and the SOC is charged and discharged between 30% and 90%;

FIG. 8 is a diagram showing the estimated value of SOH by the SOH calculation section and the actual measured value of SOH when the temperature of the secondary battery is 10° C. and the SOC is charged and discharged between 10% and 90%;

FIG. 9 is a diagram showing the errors of the calculation results of the SOH estimation section, the SOH calculation section, and the model section with respect to the actual measured SOH values for deterioration conditions A, B, and C;

FIG. 10 is a diagram showing the calculation results of the SOH estimation section, the SOH calculation section, and the model section and the actual measured value of SOH for the deterioration condition A;

FIG. 11 is a diagram showing the calculation results of the SOH estimation section, the SOH calculation section, and the model section and the actual measured value of SOH for the deterioration condition B;

FIG. 12 is a diagram showing the calculation results of the SOH estimation section, the SOH calculation section, and the model section and the actual measured value of SOH for the deterioration condition C;

FIG. 13 is a diagram showing a flow of preprocessing and calculation for sensing data according to a second embodiment;

FIG. 14 is a diagram showing a flow of preprocessing and calculation for sensing data according to a third embodiment;

FIG. 15 is a diagram showing a configuration of a battery diagnostic system according to a fourth embodiment;

FIG. 16 is a diagram showing a flow of calculating SOH according to the fourth embodiment;

FIG. 17 is a diagram showing the accuracy of calculation results when the product of parameters is included in the calculation of SOH; and

FIG. 18 is a diagram showing the accuracy of calculation results when the product of parameters is not included in the calculation of SOH.

### DETAILED DESCRIPTION

In an assumable example, a method for diagnosing a remaining life of a secondary battery module is proposed. Specifically, a remaining life diagnostic device acquires charging information of a secondary battery module from a charger, and calculates a degree of deterioration of the secondary battery module as an actual value based on the charging information. Here, the degree of deterioration is a current full charge capacity relative to the capacity of a new battery. The degree of deterioration is SOH (State of Health). Further, the remaining life diagnostic device acquires output information of the secondary battery module, and calculates a predicted value of the degree of deterioration using a prediction formula based on the output information.

Then, the remaining life diagnostic device compares an actual measured value and a predicted value, and calculates the remaining life when a difference between the actual measured value and the predicted value is less than or equal to a predetermined value. When the difference between the actual measurement value and the predicted value exceeds the predetermined value, the remaining life diagnostic device corrects the prediction formula based on the actual measurement value. The remaining life diagnostic device calculates the predicted value again using the corrected prediction formula, and calculates the remaining life when the difference between the actual measurement value and the predicted value is less than or equal to the predetermined value.

However, in the above-mentioned technology, the actual value as the degree of deterioration of the secondary battery module calculated by the remaining life diagnostic device is obtained based on section capacity measurement by current integration. For this reason, since the actual measured value includes sensing errors in the charger and logic errors in the calculation process, it is difficult to predict the remaining life with high accuracy.

In view of the above points, the present disclosure aims to provide a battery diagnostic system that can improve the accuracy of estimating the SOH of a secondary battery.

According to the first and second aspects of the present disclosure, the battery diagnostic system estimates the SOH that indicates the degree of deterioration of the secondary battery.

In a first aspect, a battery diagnostic system includes a model section, a SOH calculation section, and a SOH estimation section.

The model section acquires usage history data indicating an usage state of the secondary battery, and calculates the SOH based on the usage history data. The SOH calculation section acquires physical quantities that change depending on the degree of deterioration of the secondary battery as sensing data, and calculates the SOH based on the sensing data. Based on the SOH calculated by the model section and the SOH calculated by the SOH calculation section, the SOH estimation section combines both calculation results to estimate an optimal SOH.

According to this configuration, both errors caused by cell variations in the secondary battery that occur in the model section and sensing errors that occur in the SOH calculation section are optimized in the SOH estimation section. Therefore, the influence of the SOH sensing error calculated by the SOH calculation section can be reduced. Therefore, the accuracy of estimating the SOH of the secondary battery can be improved.

In a second aspect, the battery diagnostic system includes a data acquisition unit, a data processing unit, and a calculation unit.

The data acquisition unit acquires time-series data indicating the usage state of the secondary battery. The data processing unit acquires time series data from the data acquisition unit and processes the time series data as histogram data.

The calculation unit calculates the SOH as an estimated value using either the time series data acquired by the data acquisition unit or the histogram data acquired by the data processing unit based on a preset calculation model.

According to this configuration, SOH is estimated using either time series data or histogram data of the secondary battery. Therefore, the presence of errors such as sensing errors can be reduced more than in the current integration method. Therefore, the accuracy of estimating the SOH of the secondary battery can be improved.

The following will describe embodiments for carrying out the present disclosure with reference to the drawings. In the respective embodiments, parts corresponding to matters already described in the preceding embodiments are given reference numbers identical to reference numbers of the matters already described. The same description is therefore omitted depending on circumstances. In a case where only a part of the configuration is described in each embodiment, the other embodiments described above can be applied to the other part of the configuration.

The present disclosure is not limited to combinations of embodiments which combine parts that are explicitly described as being combinable. As long as no problem is present, the various embodiments may be partially combined with each other even if not explicitly described.

### First Embodiment

Hereinafter, a first embodiment will be described with reference to the drawings. A battery diagnostic system according to the present embodiment is a system that estimates SOH, which indicates a degree of deterioration of a secondary battery.

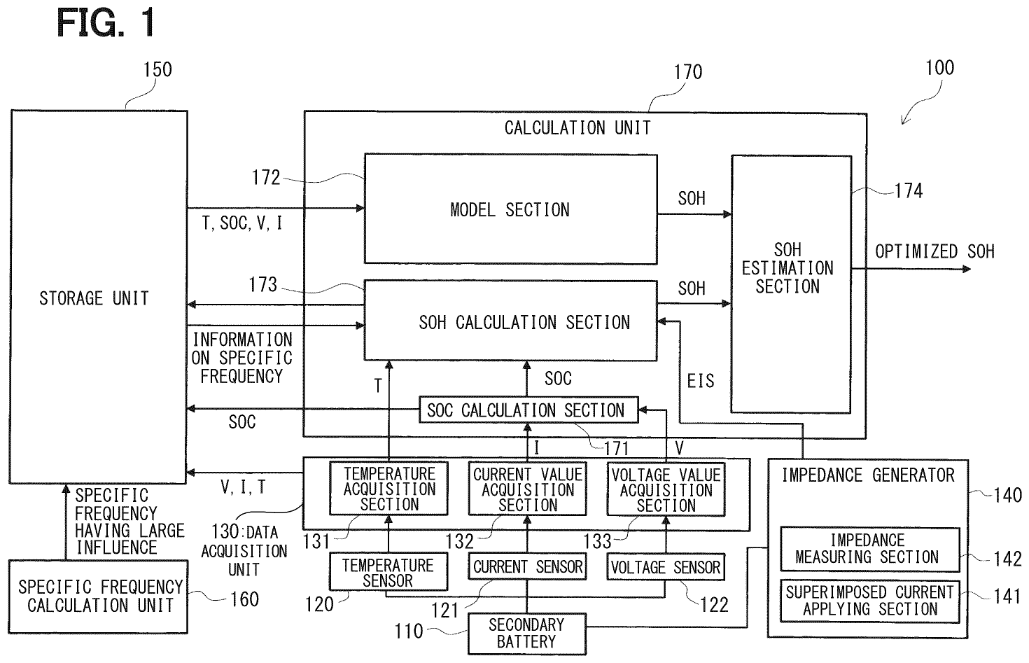

As shown in FIG. 1, the battery diagnostic system 100 includes a secondary battery 110, a temperature sensor 120, a current sensor 121, a voltage sensor 122, and a data acquisition unit 130. The battery diagnostic system 100 also includes an impedance generator 140, a storage unit 150, a specific frequency calculation unit 160, and a calculation unit 170.

The secondary battery 110 constitutes a battery module in which a plurality of battery cells are connected in series. Each battery cell is, for example, a lithium ion secondary battery. The secondary battery 110 constitutes a power supply unit of an electric vehicle such as an electric car or a hybrid car. The battery module may include a configuration in which each battery cell is connected in parallel.

The temperature sensor 120 measures the temperature of secondary battery 110. The temperature sensor 120 is installed in secondary battery 110. The current sensor 121 measures a current value of the secondary battery 110. The current sensor 121 is connected to the secondary battery 110. The voltage sensor 122 measures a voltage value of the secondary battery 110. The voltage sensor 122 is connected to the secondary battery 110. Each sensor 120 to 122 outputs a detection signal to the data acquisition unit 130 at any time.

The data acquisition unit 130 periodically acquires each data of the temperature, current value, and voltage value of the secondary battery 110. For this reason, the data acquisition unit 130 includes a temperature acquisition section 131, a current value acquisition section 132, and a voltage value acquisition section 133.

The temperature acquisition section 131 periodically acquires information on the temperature T of the secondary battery 110 measured by the temperature sensor 120. For example, the temperature acquisition section 131 calculates the temperature T from the temperature distribution of the secondary battery 110 acquired over a certain period of time. For example, the temperature T can be an average value calculated from a frequency distribution of the temperature of the secondary battery 110 acquired over a certain period of time. The temperature acquisition section 131 outputs information on the temperature T of the secondary battery 110 to the calculation unit 170.

As the temperature T, in order to reduce the calculation load, it is also possible to use, for example, an average value of the temperatures of the secondary battery 110 acquired over a certain period of time.

The current value acquisition section 132 periodically acquires information on the current I of the secondary battery 110 measured by the current sensor 121. For example, the current value acquisition section 132 calculates the current I from the distribution of the current of the secondary battery 110 acquired over a certain period of time. For example, the current I can be an average value calculated from the frequency distribution of the current of the secondary battery 110 acquired over a certain period of time. The current value acquisition section 132 outputs information about the current I of the secondary battery 110 to the calculation unit 170.

As the current I, in order to reduce the calculation load, it is also possible to use, for example, an average value of the current of the secondary battery 110 acquired over a certain period of time.

The voltage value acquisition section 133 periodically acquires information on the voltage V of the secondary battery 110 measured by the voltage sensor 122. For example, the voltage V can be an average value calculated from a frequency distribution of voltage values of the secondary battery 110 acquired over a certain period of time. The voltage value acquisition section 133 outputs information on the voltage V of the secondary battery 110 to the calculation unit 170.

As the voltage V, in order to reduce the calculation load, it is also possible to use, for example, an average value of the voltage of the secondary battery 110 acquired over a certain period of time.

Further, the data acquisition unit 130 also stores information on the temperature T acquired by the temperature acquisition section 131, information on the current I acquired by the current value acquisition section 132, and information on the voltage V acquired by the voltage value acquisition section unit 133 in the storage unit 150 as usage history data indicating the usage status of the secondary battery 110.

The usage history data includes a time series data and a histogram data. The time series data includes data on the temperature T, the SOC, the voltage V, and the current I of the secondary battery 110. The histogram data is a data obtained by processing time series data into a histogram. The SOC is acquired by the calculation unit 170, which will be described later.

The impedance generator 140 is a device that obtains the impedance of the secondary battery 110 by an electrochemical impedance spectroscopy (EIS). The impedance is a physical quantity that changes depending on the degree of deterioration of the secondary battery 110. The impedance data EIS is a sensing data measured by the impedance generator 140. The impedance generator 140 includes a superimposed current applying section 141 and an impedance measuring section 142.

The superimposed current applying section 141 applies a superimposed current in which a plurality of frequency components are superimposed to the secondary battery 110. By using the superimposed current, it is possible to collectively acquire the battery voltage when currents of a plurality of frequencies are applied to the secondary battery 110.

For example, a multiple sine wave can be employed as the superimposed current. As the superimposed current, a rectangular wave, a sawtooth wave, or a triangular wave can also be used. Here, with a harmonic wave for a fundamental frequency as the superposition frequency, the current value greatly decreases every time the order increases, but the current value does not decrease with the multiple sine wave. Thus, by employing the multiple sine wave as the superimposed current, high measurement accuracy can be maintained. In the multiple sinusoidal wave, the frequency to be superimposed is not particularly limited and can be set as appropriate.

The impedance measuring section 142 obtains the current value of the superimposed current applied to the secondary battery 110 by the superimposed current applying section 141. Furthermore, the impedance measuring section 142 acquires a response voltage when the superimposed current is applied to the secondary battery 110. Therefore, the impedance is a value calculated by dividing the response voltage by an alternating current as a complex number having information of an absolute value and a phase after the response voltage corresponding to the alternating current applied to the secondary battery 110 is measured. That is, the impedance includes a real component Zreal and an imaginary component Zimage.

Specifically, the impedance measuring section 142 calculates the impedance of the secondary battery 110 for each of the plurality of frequency components using a discrete Fourier transform. As the current value and the voltage value at the time of applying the superimposed current, detection values of the current sensor 121 and the voltage sensor 122 can be used. A fast discrete Fourier transform (FFT) can be employed as the discrete Fourier transform.

The impedance generator 140 outputs the calculated impedance for each of the plurality of frequency components to the calculation unit 170. The impedance generator 140 may store the impedance data in the storage unit 150.

The impedance generator 140 can be configured using, for example, a power conversion device that constitutes an on-vehicle power control unit. Thereby, there is no need to separately provide the impedance generator 140 including the superimposed current generator. A superimposed current of a large current can be generated. Therefore, a device configuration suitable for on-board diagnosis of the secondary battery 110 for vehicle mounting can be achieved. Alternatively, the superimposed current generation unit can be disposed in an on-vehicle charging device which is not illustrated or a charging device provided outside.

The specific frequency calculation unit 160 is a device that obtains information on a specific frequency necessary for calculating the optimal SOH of the secondary battery 110 in advance by the electrochemical impedance spectroscopy. The specific frequency calculation unit 160 may or may not be installed on the vehicle.

That is, the specific frequency is a frequency determined by machine learning using the impedance data EIS of the secondary battery 110 acquired in advance. Further, the specific frequency is a frequency that has a large influence on the SOH of the secondary battery 110.

The optimal SOH is the SOH finally estimated by the calculation unit 170. A degree of influence on the SOH of the secondary battery 110 corresponds to a strength of a correlation between the imaginary component Zimage of impedance and the SOH. The specific frequency is, for example, a specific frequency in a frequency range greater than 1 Hz, preferably greater than 10 Hz.

The structure of the secondary battery 110 differs depending on the electric vehicle in which it is mounted. The characteristics of the secondary battery 110 differ depending on the vehicle type, for example. Therefore, the specific frequency differs depending on the configuration of the secondary battery 110. The specific frequency calculation unit 160 is used to obtain a specific frequency corresponding to the secondary battery 110 mounted on the electric vehicle. The method for obtaining the specific frequency will be explained later.

The storage unit 150 is, for example, a rewritable nonvolatile memory. The storage unit 150 stores programs for controlling the data acquisition unit 130, the impedance generator 140, and the calculation unit 170. Furthermore, the storage unit 150 stores the usage history data input from the data acquisition unit 130 and the calculation unit 170 as needed.

Furthermore, the storage unit 150 stores information on a plurality of specific frequencies within the frequency range used in the electrochemical impedance spectroscopy measurements in the impedance generator 140. The information on a plurality of specific frequencies is input in advance from the specific frequency calculation unit 160.

The calculation unit 170 estimates the optimal SOH of the secondary battery 110. The calculation unit 170 is configured by a device such as a processor. The calculation unit 170 includes an SOC calculation section 171, a model section 172, a SOH calculation section 173, and a SOH estimation section 174.

The SOC calculation section 171 calculates a charging rate indicating the battery remaining quantity of the secondary battery 110. The charging rate of the secondary battery 110 is expressed as a percentage of the remaining capacity to the fully charged capacity of the secondary battery 110. The charging rate of the secondary battery 110 is SOC (State Of Charge).

For example, the SOC calculation section 171 calculates the integrated value of the current value of the secondary battery 110 acquired by the current value acquisition section 132, and calculates the charging rate of the secondary battery 110 based on the integrated value. The SOC information calculated by the SOC calculation section 171 is stored in the storage unit 150 and is output to the SOH calculation section 173.

The model section 172 acquires the usage history data of the secondary battery 110 from the storage unit 150. Furthermore, the model section 172 calculates the SOH by applying the usage history data to a theoretical formula that is a preset calculation model. The model section 172 outputs the calculated SOH to the SOH estimation section 174.

The SOH calculation section 173 acquires an impedance data EIS from the impedance generator 140 as sensing data. The SOH calculation section 173 converts the impedance data EIS into data at a predetermined temperature and a predetermined SOC using a temperature conversion model and an SOC conversion model. The predetermined temperature is, for example, 25° C. The predetermined SOC is, for example, 50%. Thereby, it is possible to calculate the SOH that does not depend on the environment in which the secondary battery 110 is placed or the state of the secondary battery 110.

The SOH calculation section 173 does not use all the impedance data EIS corresponding to the measurement frequency, but uses the impedance data EIS corresponding to a plurality of specific frequencies stored in the storage unit 150. That is, the SOH calculation section 173 calculates the SOH based on the machine learning using as input the imaginary component Zimage of the impedance corresponding to a plurality of specific frequencies among the impedance data EIS. Thereby, the number of input data used by the SOH calculation section 173 can be reduced. Therefore, a calculation load on the SOH calculation section 173 can be reduced.

Specifically, the SOH calculation section 173 calculates the SOH using Gaussian Process Regression (GPR) using the impedance data EIS as input as a machine learning method. The GPR is one of the models that estimates a predicted value using current and past states as input values. By not using the real component Zreal of impedance with a large measurement error, an accuracy of estimating the SOH calculated by the SOH calculation section 173 is improved. Furthermore, since a machine learning method is used, an estimation accuracy of SOH is improved compared to the current integration method. The SOH calculation section 173 outputs the calculated SOH to the SOH estimation section 174.

Based on the SOH calculated by the model section 172 and the SOH calculated by the SOH calculation section 173, the SOH estimation section 174 combines both calculation results to estimate an optimal SOH. Specifically, the SOH estimation section 174 corrects the SOH calculated by the model section 172 with the SOH calculated by the SOH calculation section 173. The SOH estimation section 174 calculates the degree of correction based on the SOH variance calculated by the model section 172 and the noise variance of the SOH calculation section 173, and estimates a final SOH.

The SOH estimation section 174 obtains the estimation result of the optimal SOH several times a day or once a day, for example. Of course, the estimation frequency of the optimal SOH is not limited to these frequencies, and a necessary frequency is set as appropriate.

Specifically, the SOH estimation section 174 estimates the optimal SOH using a nonlinear Kalman filter. The nonlinear Kalman filter is preferably an extended Kalman filter. The above description relates to an entire configuration of the battery diagnostic system 100 according to the present embodiment.

Next, an operation of the calculation unit 170 will be explained. First, the model section 172 calculates the SOH based on the usage history data stored in the storage unit 150 and outputs the calculated SOH to the SOH estimation section 174.

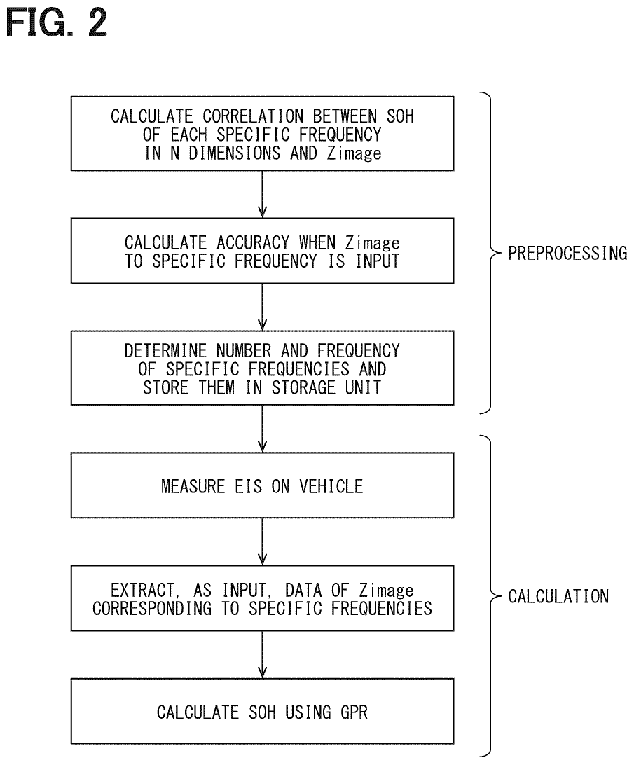

Further, the SOH calculation section 173 calculates the SOH based on the impedance input from the impedance generator 140. Here, the SOH calculation section 173 calculates the SOH using information on a plurality of specific frequencies stored in the storage unit 150. As shown in FIG. 2, the information on a plurality of specific frequencies is obtained in advance in preprocessing.

For example, it is assumed that the secondary battery 110 has a capacity of 50 Ah and has an NCM622/Gr configuration. The configuration of the secondary battery 110 used when acquiring specific frequency information in advance in preprocessing is the same as the configuration of the secondary battery 110 employed in the battery diagnostic system 100.

In a first processing, the correlation between the SOH of each specific frequency in N dimensions and the imaginary component Zimage of impedance is calculated. For this reason, the secondary battery 110 is degraded in advance under various conditions. The deterioration conditions include, for example, storage at different temperatures and SOCs, and repeated charging and discharging at different temperatures, center SOCs, and ΔDODs. Further, a transition of SOH and the imaginary component Zimage of impedance until an end of the life of the secondary battery 110 are acquired as data.

The DOD (Depth Of Discharge) indicates the depth of discharge of the secondary battery 110. ΔDOD is calculated, for example, by a difference between the SOC at a start of charging and discharging and the SOC at an end of charging and discharging.

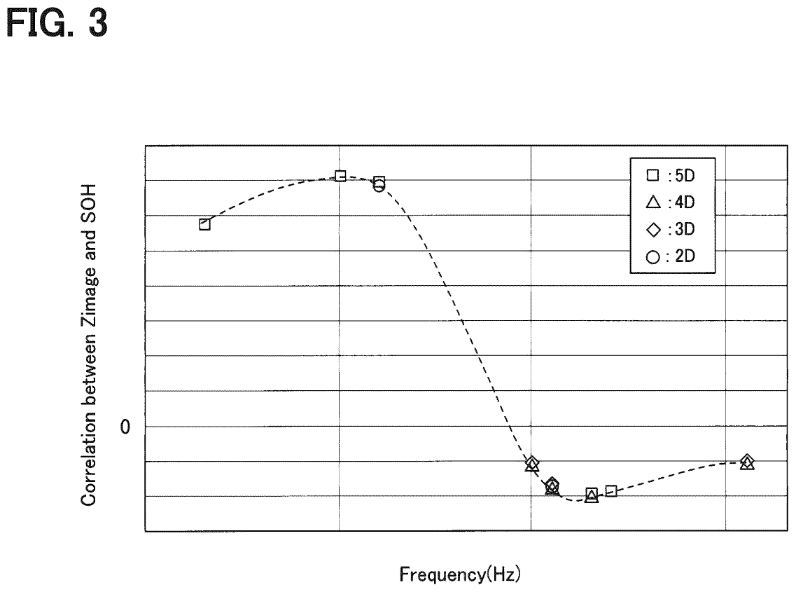

As a result, as shown in FIG. 3, a correlation between the relationship between the imaginary component Zimage of the impedance and the SOH and a certain range of frequencies can be obtained. A horizontal axis in FIG. 3 is on a logarithmic scale. The larger the value indicating the relationship between the imaginary component Zimage of impedance and the SOH, the higher the importance.

Here, if all frequencies within a certain range are used to estimate the SOH, an overfitting may occur. Therefore, the error in the extrapolation area increases. Therefore, the larger the number of frequencies, that is, the number of dimensions, is not necessarily better. Therefore, using the data shown in FIG. 3, SISSO, which is a type of machine learning, is used to calculate combinations of specific frequencies up to N dimensions. In other words, it is determined which frequency within a certain range of frequencies is to be used for SOH estimation. The frequency determined thereby becomes the specific frequency. By specifying several frequencies to be used for SOH estimation, the versatility of the specific frequencies can be increased.

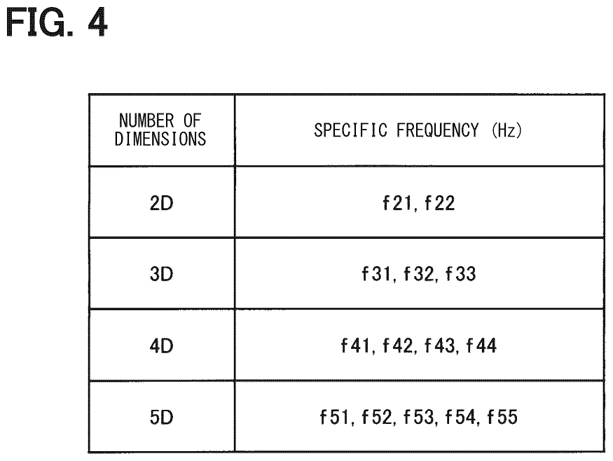

Through the above machine learning, a combination of the number of dimensions and the specific frequency is derived, as shown in FIG. 4. In the case of two dimensions, two specific frequencies, f21 and f22, are determined. The two frequencies correspond to two frequencies of the correlation lines shown in FIG. 3 Similarly, in the case of three dimensions, three frequencies, f31, f32, and f33, are determined, which correspond to three frequencies among the correlation lines shown in FIG. 3. A plurality of frequencies are similarly determined in the case of four-dimensions and the case of five-dimensions.

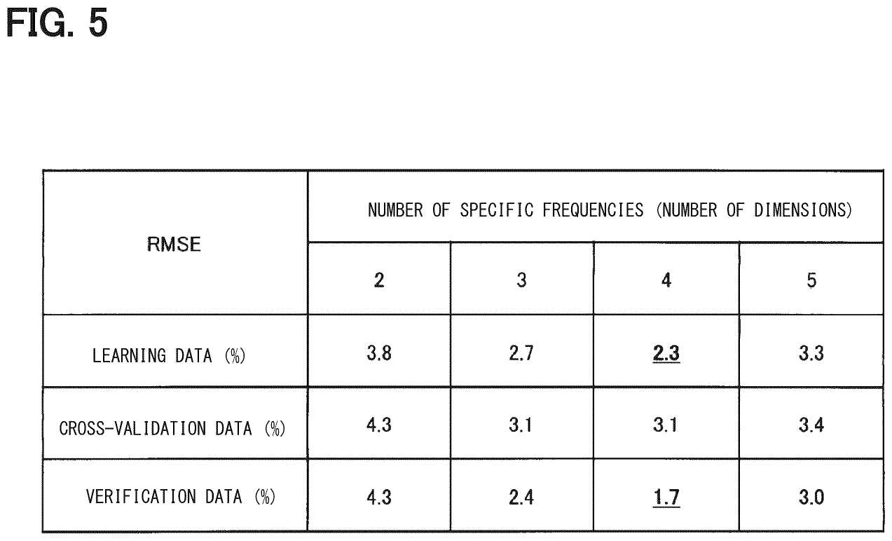

Subsequently, as shown in FIG. 2, the accuracy of the SOH is calculated when the imaginary component Zimage of the impedance corresponding to each specific frequency is input. The results are illustrated in FIG. 5.

In FIG. 5, the learning data is a data actually used for machine learning. A cross-validation data is, for example, a data that is used as learning data by excluding data for one type of deterioration condition from all data for a plurality of types of deterioration conditions, and that was subjected to machine learning by using one type of data that was removed as verification data, and changing all of the multiple types of data into verification data in order. A verification data is an unknown data that is not used for machine learning. RMSE indicates a root mean square error (%) of each data with respect to the SOH of the actual measurement value.

The actual measured value of SOH is calculated from a formula, (current battery capacity/initial battery capacity)×100 (%), when the temperature of the secondary battery 110 is 25° C., the SOC of the secondary battery 110 is charged and discharged between 0% and 100%, and the current of the secondary battery 110 is C/3,

Then, the number of dimensions that minimizes the error of each data with respect to the actual measured value of SOH is calculated. In the example shown in FIG. 5, the error in the case of four-dimensions is minimized. In this case, there are four specific frequencies. In this way, the specific frequency calculation unit 160 determines the number and frequency of specific frequencies. Thereafter, the specific frequency calculation unit 160 stores the information on the number and frequency of specific frequencies in the storage unit 150. The preprocessing is thus completed.

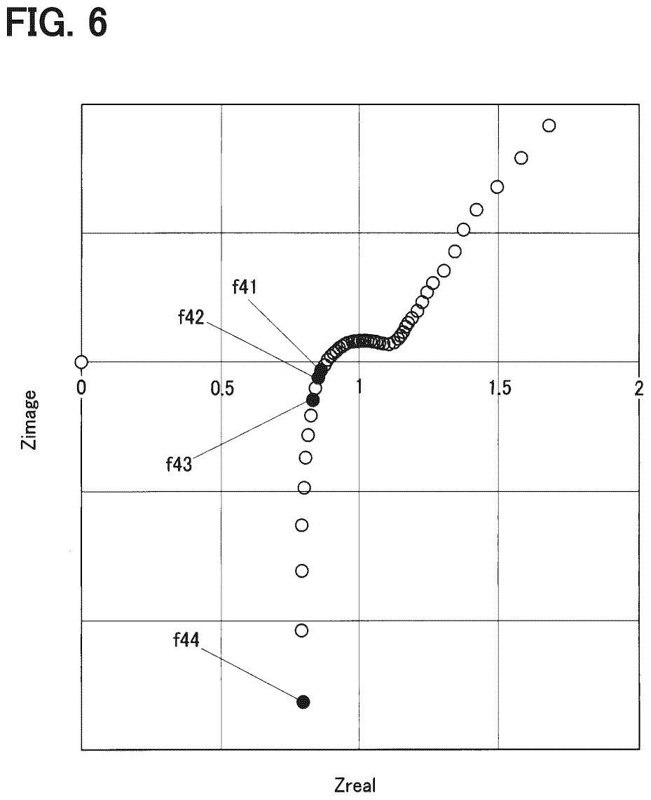

The SOH calculation section 173 executes the calculation flow shown in FIG. 2 using the information on the four specific frequencies acquired in advance as described above. For this reason, first, the SOH calculation section 173 acquires the impedance data EIS measured by the impedance generator 140. As shown in FIG. 6, the impedance has a real component Zreal and an imaginary component Zimage that change depending on the frequency.

The SOH calculation section 173 converts the impedance data EIS into a data at a temperature of 25° C. and an SOC of 50%, for example, using a temperature conversion model and an SOC conversion model. Therefore, it is possible to calculate SOH at any temperature or SOC.

Subsequently, the SOH calculation section 173 requests the information on the four specific frequencies from the storage unit 150 and acquires the information on the four specific frequencies from the storage unit 150. Further, the SOH calculation section 173 extracts, as input, the imaginary components Zimage corresponding to four specific frequencies from the impedance data group shown in FIG. 6.

Thereafter, the SOH calculation section 173 calculates the SOH using GPR with four imaginary components of impedance Zimage as input. The SOH calculation section 173 outputs the calculated SOH to the SOH estimation section 174.

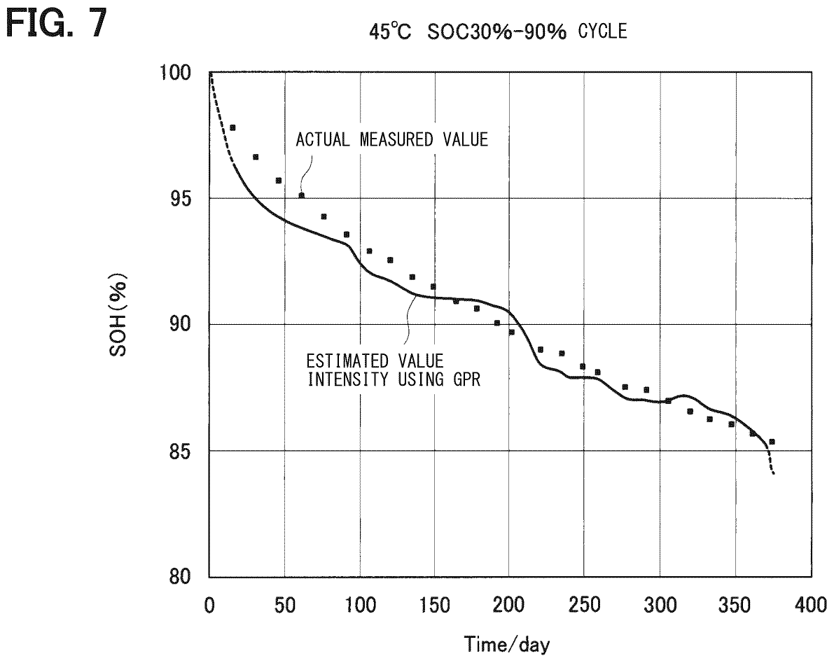

The present disclosers calculated the SOH of the SOH calculation section 173 when the temperature of the secondary battery 110 was set to 45° C. and a plurality of cycles of charging and discharging the SOC between 30% and 90% were repeated. The results are illustrated in FIG. 7. A horizontal axis of FIG. 7 is the number of days. As shown in FIG. 7, the estimated value of SOH using GPR was close to the actual measured value of SOH.

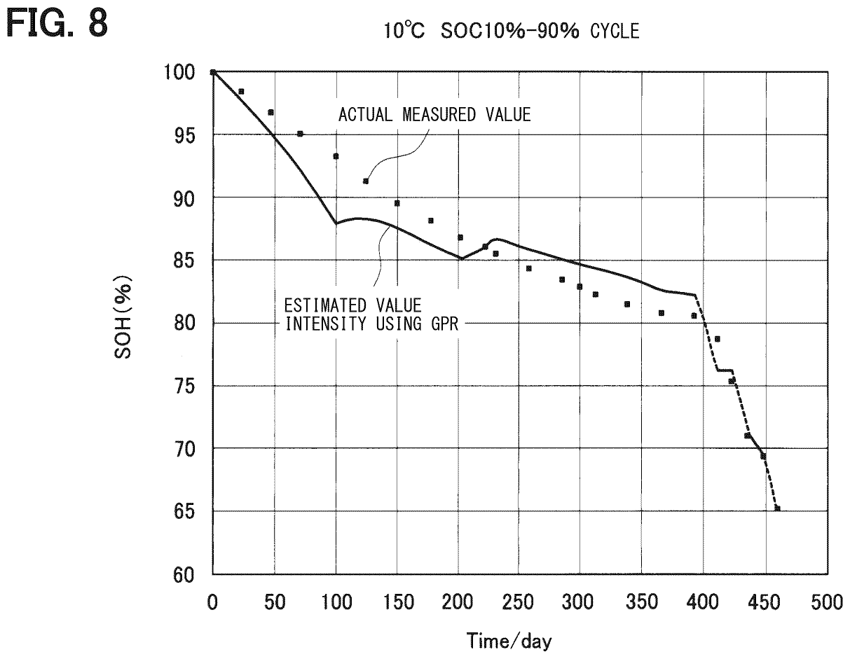

The present disclosers calculated the SOH of the SOH calculation section 173 when the temperature of the secondary battery 110 was set to 10° C. and a plurality of cycles of charging and discharging the SOC between 10% and 90% were repeated. The results are illustrated in FIG. 8. A horizontal axis of FIG. 8 is the number of days. As shown in FIG. 8, even when the secondary battery 110 was placed in a cold environment, the estimated value of SOH using GPR did not deviate greatly from the actual measured value of SOH.

The SOH estimation section 174 uses the SOH calculated by the model section 172 and the SOH calculated by the SOH calculation section 173 as described above to estimate the optimal SOH by an extended Kalman filter. Hereinafter, the optimal SOH will be referred to as an optimized SOH. The SOH estimation section 174 outputs the optimized SOH to an external device. The external device is used for displaying the obtained optimized SOH to an user, controlling charging and discharging of the secondary battery 110, and the like.

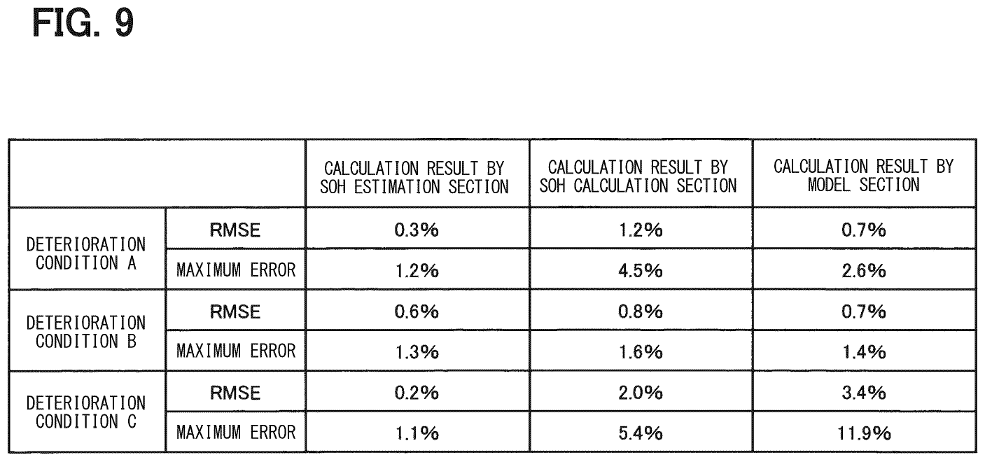

The present disclosers compared the calculation results calculated by the model section 172, the calculation results calculated by the SOH calculation section 173, and the calculation results calculated by the SOH estimation section 174 under a plurality of deterioration conditions with the actual measured value of SOH. The results are illustrated in FIG. 9.

A deterioration condition A is a case where the temperature of the secondary battery 110 is 45° C., and a plurality of cycles of charging and discharging the SOC between 0% and 100% are repeated. A deterioration condition B is a case where the temperature of the secondary battery 110 is 45° C., and a plurality of cycles of charging and discharging at an SOC between 30% and 90% are repeated. A deterioration condition C is a case where the temperature of the secondary battery 110 is 10° C., and a plurality of cycles of charging and discharging the SOC between 10% and 90% are repeated. The current during charging under each deterioration condition A, B, and C is 0.3 C, and the current during discharging is 1 C. Furthermore, the method for measuring the actual value of SOH is the same as described above.

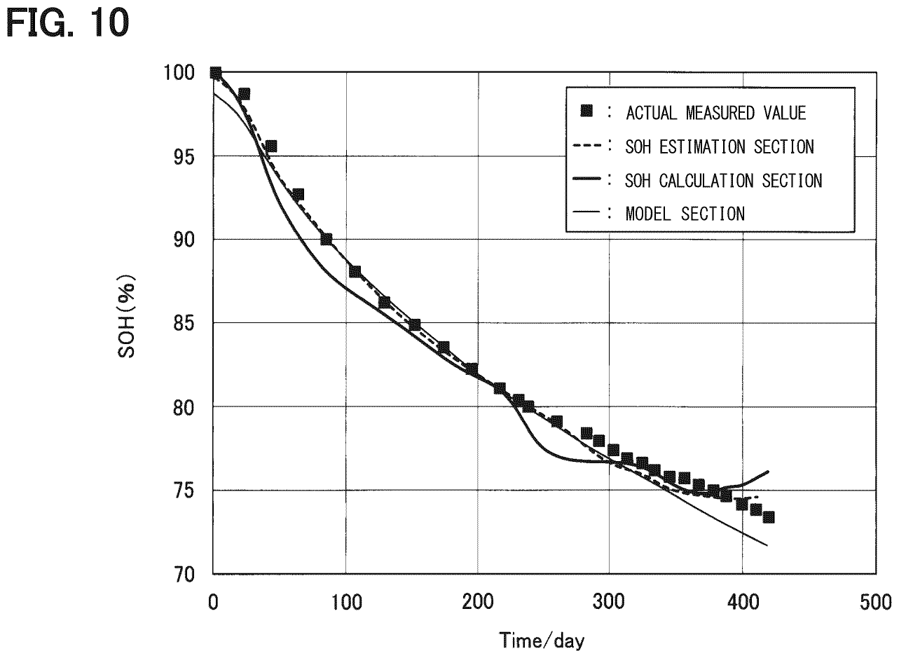

As shown in FIGS. 9 and 10, under the deterioration condition A, the error in the SOH calculation result by the model section 172 was 0.7%, and the maximum error was 2.6%. The error in the SOH calculation result by the SOH calculation section 173 was 1.2%, and the maximum error was 4.5%.

On the other hand, the error in the optimized SOH calculation result by the SOH estimation section 174 was 0.3%, and the maximum error was 1.2%. Obviously, the optimized SOH by the SOH estimation section 174 is closer to the actual measured value of the SOH than the calculation results by the model section 172 and the SOH calculating section 173.

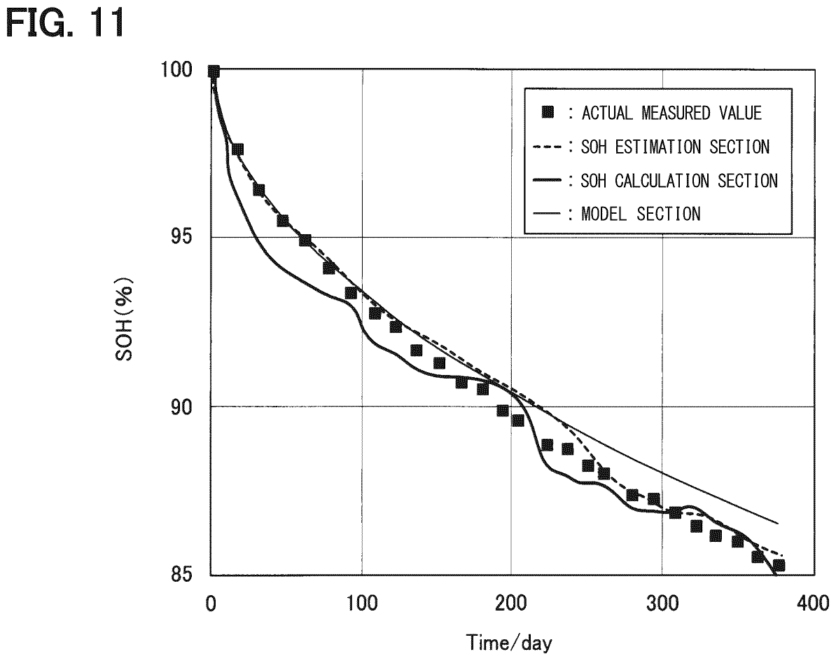

In the deterioration condition B, as shown in FIGS. 9 and 11, although the errors in each calculation result were originally small, the optimized SOH by the SOH estimation section 174 became a value closer to the actual measured value of SOH.

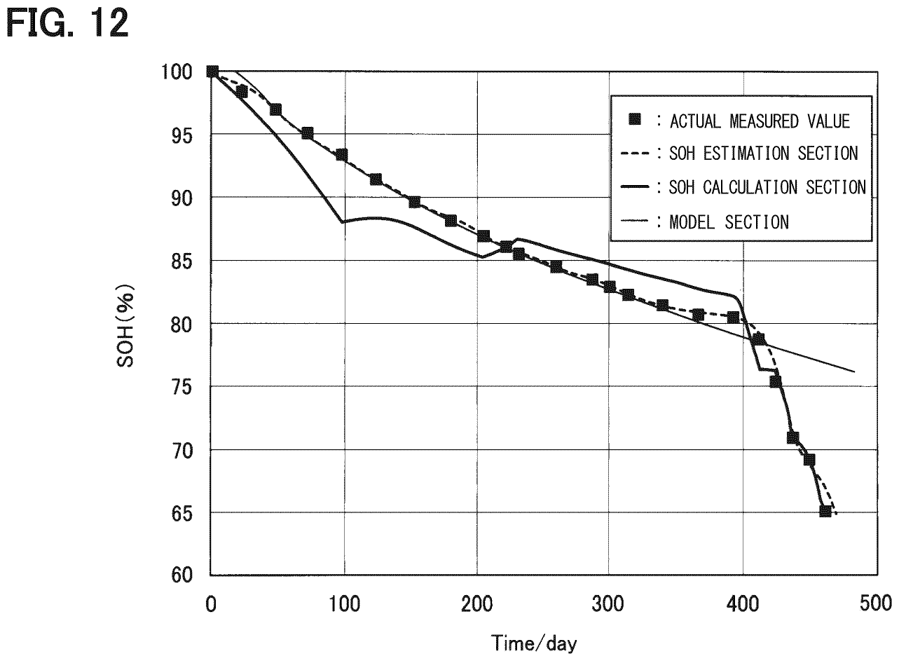

In the deterioration condition C, as shown in FIGS. 9 and 12, the difference between the error of the optimized SOH by the SOH estimation section 174 and the error of each calculation result by the model section 172 and the SOH calculation section 173 became large.

In the deterioration condition C, it is considered to be due to abnormal deterioration caused by lithium precipitation in the secondary battery 110 after 400 days had passed. Therefore, the SOH of the secondary battery 110 is rapidly decreasing. The calculation results by the model section 172 cannot follow the rapid decrease in SOH. However, since the SOH calculation section 173 calculates the SOH using the imaginary component Zimage of the impedance, which is the sensing data, the calculation result of the SOH calculation section 173 was able to follow the rapid decrease in the SOH. In other words, it can be said that the accuracy of the estimated SOH value can be improved using only the SOH calculation section 173.

As explained above, in the present embodiment, the calculation results by the model section 172 and the calculation results of the SOH calculation section 173 are combined and optimized in the SOH estimation section 174. Specifically, based on the SOH calculated by the model section 172, the SOH estimation section 174 corrects the SOH by the model section 172 with the SOH as an actual value calculated by the SOH calculation section 173, and estimates the final SOH.

According to this configuration, both errors caused by cell variations in the secondary battery 110 that occur in the model section 172 and sensing errors that occur in the SOH calculation section 173 are optimized in the SOH estimation section 174. Therefore, the influence of the SOH sensing error calculated by the SOH calculation section 173 can be reduced. Therefore, the accuracy of estimating the SOH of the secondary battery 110 can be improved.

As a modification, the battery diagnostic system 100 may employ only the calculation result of the SOH calculation section 173 as the estimated value of SOH. The SOH calculation section 173 acquires physical quantities that change depending on the degree of deterioration of the secondary battery 110 as sensing data, and calculates the SOH based on the sensing data. Therefore, the presence of errors such as sensing errors can be reduced more than in the current integration method. Therefore, the accuracy of estimating the SOH of the secondary battery 110 can be improved.

### Second Embodiment

In the present embodiment, the configurations different from those of the first embodiment will be mainly described. In the present embodiment, the SOH calculation section 173 calculates the SOH using a voltage change during charging of the secondary battery 110 as sensing data.

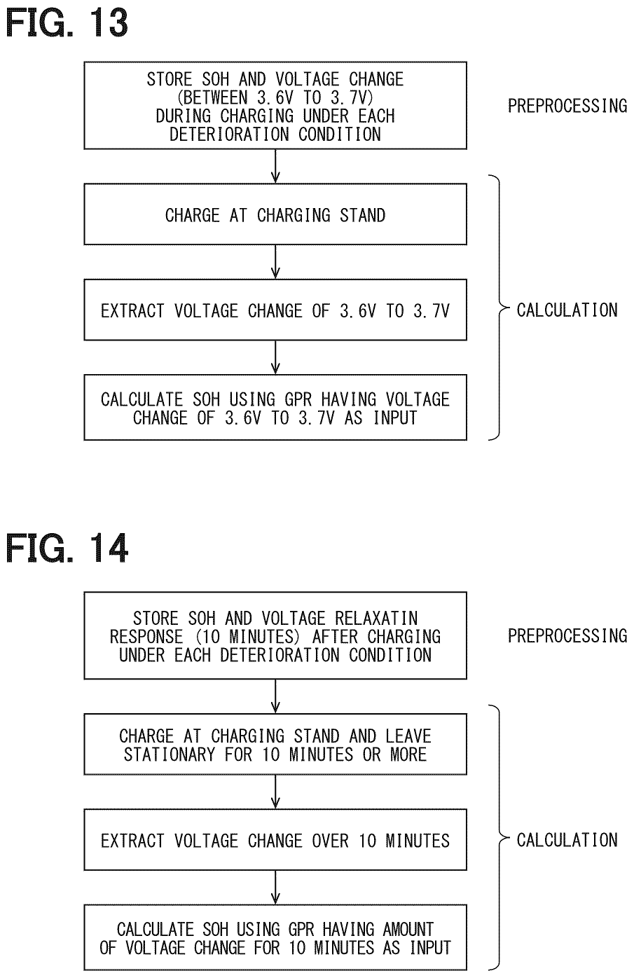

For this reason, as shown in FIG. 13, in the preprocessing, the secondary battery 110 is degraded in advance under various deterioration conditions, and a transition of the SOH until the life of the secondary battery 110 is obtained. Further, voltage change during charging under deterioration conditions are acquired and stored in the storage unit 150 in advance.

The voltage change is, for example, the changes in voltage value in a range from 3.6V to 3.7V. The voltage range from 3.6V to 3.7V is a region where the voltage value changes significantly when the secondary battery 110 deteriorates. The present disclosers have clarified through extensive studies that there is a correlation between the voltage change and the SOH in such voltage range. In other words, the voltage value is a physical quantity that changes depending on the degree of deterioration of the secondary battery 110.

In a state where the above preprocessing is completed, for example, the secondary battery 110 is charged at a charging stand. The SOH calculation section 173 acquires the voltage change of the secondary battery 110 acquired by the data acquisition unit 130 via the storage unit 150.

Further, the SOH calculation section 173 extracts the voltage change of 3.6V to 3.7V from among the voltage change acquired by the data acquisition unit 130. Then, the SOH calculation section 173 calculates the SOH using GPR having the voltage change of 3.6V to 3.7V as input. In this way, the SOH can also be calculated using the voltage change during charging of the secondary battery 110 as sensing data.

As a modification, the voltage change may be a change in voltage value in a range from 4.0V to 4.1V. The accuracy of SOH estimation can also be improved in this voltage range. Of course, it is not limited to the range from 3.6V to 3.7V and the range from 4.0V to 4.1V, and other voltage ranges may be set.

### Third Embodiment

In the present embodiment, portions different from those of the first and second embodiments will be mainly described. In the present embodiment, the SOH calculation section 173 calculates the SOH using the amount of voltage change in relaxation of charging voltage as sensing data.

For this reason, as shown in FIG. 14, in the preprocessing, the secondary battery 110 is degraded in advance under various deterioration conditions, and a transition of the SOH until the life of the secondary battery 110 is obtained. Further, the relaxation response of the voltage after charging under the deterioration condition is acquired and stored in the storage unit 150 in advance.

The relaxation response of the voltage is, for example, the amount of voltage change over 10 minutes. The disclosers of the present invention have found, after extensive study, that the relaxation response of the voltage after charging is correlated with the SOH. In other words, the amount of voltage change in the relaxation response of the voltage is a physical quantity that changes depending on the degree of deterioration of the secondary battery 110.

In a state where the above preprocessing is completed, for example, the secondary battery 110 is charged at a charging stand and left stationary for 10 minutes or more. The SOH calculation section 173 acquires the amount of voltage change of the secondary battery 110 acquired by the data acquisition unit 130 via the storage unit 150.

Furthermore, the SOH calculation section 173 extracts the amount of voltage change over 10 minutes from among the voltage changes acquired by the data acquisition unit 130. Then, the SOH calculation section 173 calculates the SOH using GPR having the amount of voltage change for 10 minutes as input. In this way, the SOH can also be calculated using the amount of voltage change during charging of the secondary battery 110 as sensing data.

### Fourth Embodiment

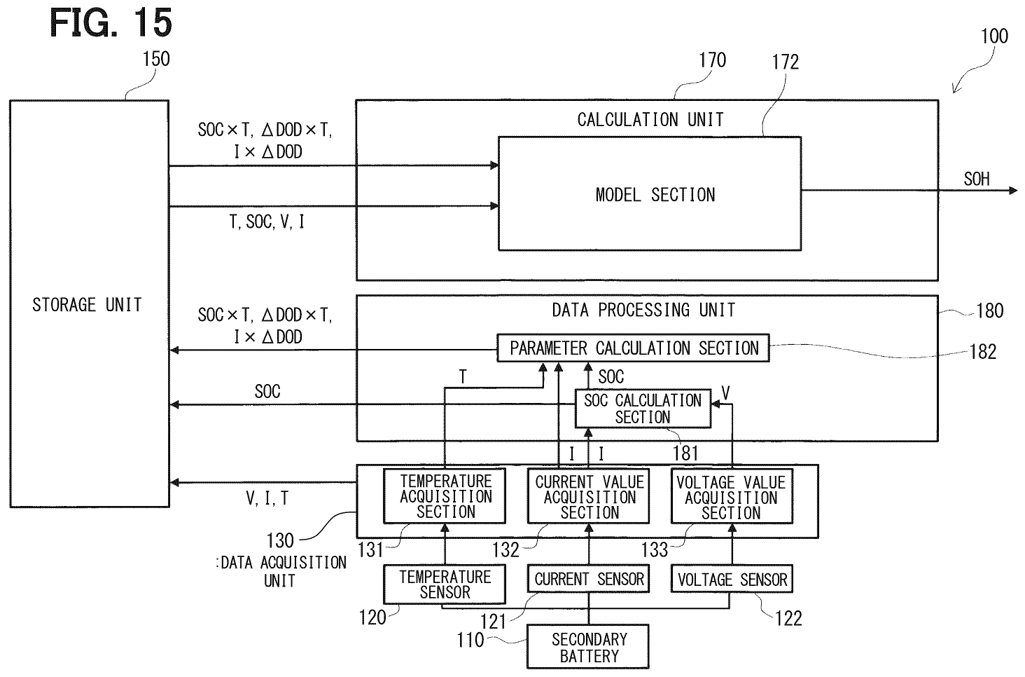

In the present embodiment, the configurations different from the respective embodiments described above will be described. As shown in FIG. 15, the battery diagnostic system 100 according to the present embodiment includes the secondary battery 110, the data acquisition unit 130, a data processing unit 180, the storage unit 150, and the calculation unit 170.

The data processing unit 180 acquires time series data from the data acquisition unit 130 and processes the time series data as histogram data. The histogram data may be processed by the data acquisition unit 130.

The data processing unit 180 includes an SOC calculation section 181 and a parameter calculation section 182. The SOC calculation section 181 has the same functions as the SOC calculation section 171 shown in the first embodiment.

The parameter calculation section 182 receives the time series data of the secondary battery 110 and processes the time series data as histogram data. The histogram data includes parameters such as SOC, temperature T, current I, and ΔDOD of the secondary battery 110.

Furthermore, the parameter calculation section 182 calculates the preset product of parameters. The product of parameters includes at least one of SOC×T, ΔDOD×T, and I×ΔDOD. The parameter calculation section 182 stores the product of the parameters in the storage unit 150. When using histogram data to estimate SOH, it becomes unnecessary to record the time-series data.

After extensive study, the present disclosers have found that by including SOC×T, ΔDOD×T, and I×ΔDOD in the calculation model of the model section 172, SOH can be predicted with high accuracy even when using histogram data as input. The C rate can also be used instead of the current I.

The calculation unit 170 has the model section 172. The model section 172 calculates the SOH as an estimated value using either the time series data or the histogram data based on a preset calculation model. When using the histogram data, the calculation unit 170 calculates the SOH using each parameter and the product of two or more of the parameters. The above is the configuration of the battery diagnostic system 100 according to the present embodiment.

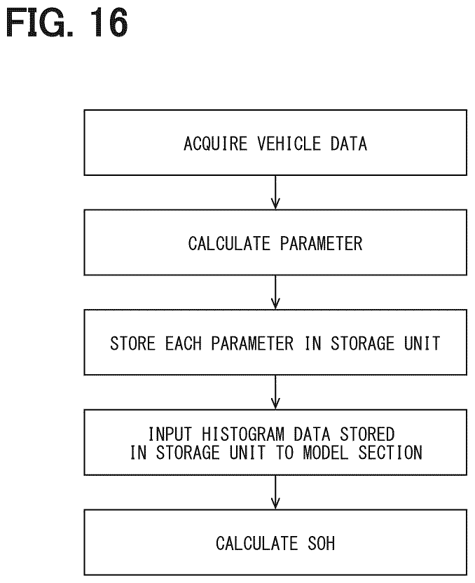

Next, a flow of estimating SOH using the histogram data will be explained. As shown in FIG. 16, the data acquisition unit 130 first acquires a vehicle data such as time series data. Subsequently, the data processing unit 180 calculates the product of the parameters in the parameter calculation section 182. Thereafter, the parameter calculation section 182 stores the calculated product of the parameters in the storage unit 150.

Then, the model section 172 of the calculation unit 170 calculates the SOH using a model set in advance using the histogram data stored in the storage unit 150 as input. That is, the model section 172 calculates the SOH by calculating f{T, SOC, I, ΔDOD, SOC×T, ΔDOD×T, I×ΔDOD} using the parameter and the product of the parameters. f is a preset calculation formula.

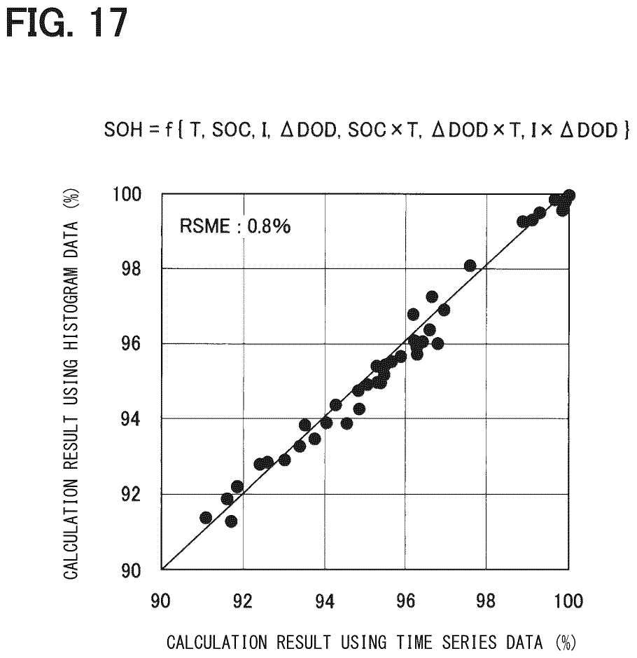

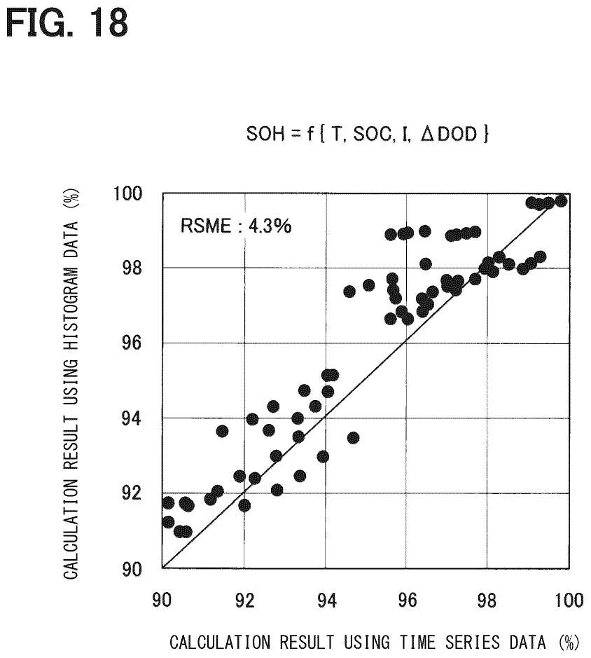

In calculating SOH under various deterioration conditions, the present disclosers compared cases in which the product of parameters was included and cases in which the product of parameters was not included, with cases in which SOH was calculated using the time series data. The results are illustrated in FIGS. 17 and 18. The various deterioration conditions are the same as those employed in the first processing in FIG. 2, for example.

As shown in FIG. 17, when the product of parameters is included in the SOH calculation, the SOH calculation results using time series data and the SOH calculation results using histogram data had an eorror of 0.8% respect to the actual SOH value. In other words, by including the product of parameters in the model, SOH estimation accuracy was improved regardless of whether the time series data or the histogram data were used.

On the other hand, as shown in FIG. 18, when the product of parameters is not included in the SOH calculation, the SOH calculation results using time series data and the SOH calculation results using histogram data had an error of 4.3% with respect to the actual SOH value. Therefore, it can be seen that the accuracy of SOH estimation can be improved by including the product of parameters in the model.

As described above, the SOH can be estimated using either the time series data or the histogram data of the secondary battery 110. At this time, since time series data or histogram data is used, the presence of errors such as sensing errors can be reduced more than in the current integration method. Therefore, the accuracy of estimating the SOH of the secondary battery 110 can be improved.

The present disclosure is not limited to the aforementioned embodiments, and various changes can be made thereto as will be described hereinafter, without departing from the spirits of the present disclosure.

For example, the secondary battery 110 is not limited to a case of being mounted on an electric vehicle, and includes a case of being installed at a predetermined place. Further, the SOH of the secondary battery 110 is not limited to the SOH of the entire secondary battery 110, and may be the SOH of a single battery cell or a plurality of SOHs of the battery cells that constitute the secondary battery 110.

Although the present disclosure has been described in accordance with the examples, it is understood that the present disclosure is not limited to the above examples or structures. The present disclosure encompasses various modifications and variations within the scope of equivalents. In addition, while the various combinations and configurations, which are preferred, other combinations and configurations, including more, less or only a single element, are also within the spirit and scope of the present disclosure.

What is claimed is:

1. A battery diagnostic system for estimating SOH (State Of Health) indicating a degree of deterioration of a secondary battery, comprising:
a model section configured to acquire an usage history data indicating a usage state of the secondary battery and calculate the SOH based on the usage history data;
a SOH calculation section configured to acquire physical quantities that change depending on the degree of deterioration of the secondary battery as sensing data, and calculate the SOH based on the sensing data; and
based on the SOH calculated by the model section and the SOH calculated by the SOH calculation section, a SOH estimation section configured to combine both calculation results to estimate an optimal SOH,
wherein
the sensing data is an impedance data of the secondary battery obtained by an electrochemical impedance spectroscopy,
the SOH calculation section calculates the SOH by a Gaussian process regression using the impedance data as input,
a storage unit in which information on a specific frequency within a frequency range used in the electrochemical impedance spectroscopy is stored in advance is included, and
the SOH calculation section calculates the SOH using an imaginary component of an impedance corresponding to the specific frequency stored in the storage unit, out of the impedance data.

2. The battery diagnostic system according to claim 1, wherein
the impedance obtained by the electrochemical impedance spectroscopy is a value calculated by dividing a response voltage by an alternating current as a complex number with an absolute value and a phase information after measuring the response voltage corresponding to the alternating current applied to the secondary battery.

3. The battery diagnostic system according to claim 1, wherein,
the specific frequency is a frequency determined based on machine learning using impedance data of the secondary battery obtained in advance by the electrochemical impedance spectroscopy, and a frequency having a large influence on the SOH of the secondary battery.

4. The battery diagnostic system according to claim 1, wherein
the sensing data is data on voltage changes during charging of the secondary battery, and
the SOH calculation section calculates the SOH by Gaussian process regression using as input data on voltage changes during charging of the secondary battery.

5. The battery diagnostic system according to claim 1, wherein
the SOH estimation section estimates the SOH using a nonlinear Kalman filter.

6. A battery diagnostic system for estimating SOH (State OF Health) indicating a degree of deterioration of a secondary battery, comprising:
a data acquisition unit configured to acquire time series data indicating an usage state of the secondary battery;
a data processing unit configured to acquire the time series data from the data acquisition unit and process the time series data as histogram data; and
a calculation unit calculates the SOH as an estimated value using either the time series data acquired by the data acquisition unit or the histogram data acquired by the data processing unit based on a preset calculation model,
wherein
the histogram data includes parameters such as SOC (State OF Charge), temperature, current, and ΔDOD (Depth Of Discharge) of the secondary battery, and
the calculation unit calculates the SOH using each of the parameters and a product of two or more of the parameters.

7. The battery diagnostic system according to claim 6, wherein
the product of parameters includes at least one of SOC×T, ΔDOD×T, and I×ΔDOD, and the temperature is defined as T and the current is defined as I.

8. A battery diagnostic system for estimating SOH (State Of Health) indicating a degree of deterioration of a secondary battery, comprising:
a computer including a processor and a memory that stores instructions configured to, when executed by the processor, cause the processor to
acquire an usage history data indicating a usage state of the secondary battery and calculate a first SOH based on the usage history data;
acquire physical quantities that change depending on the degree of deterioration of the secondary battery as sensing data, and calculate a second SOH based on the sensing data;
combine both calculation results to estimate an optimal SOH, based on the first SOH and the second SOH; and
store information on a specific frequency within a frequency range used in an electrochemical impedance spectroscopy in advance,
wherein
the sensing data is an impedance data of the secondary battery obtained by the electrochemical impedance spectroscopy, and
the computer causes the processor to calculate the SOH by a Gaussian process regression using the impedance data as input and calculates the SOH using an imaginary component of an impedance corresponding to the stored specific frequency, out of the impedance data.

9. A battery diagnostic system for estimating SOH (State Of Health) indicating a degree of deterioration of a secondary battery, comprising:
a computer including a processor and a memory that stores instructions configured to, when executed by the processor, cause the processor to
acquire time series data indicating an usage state of the secondary battery;
process the time series data as histogram data; and
calculate the SOH as an estimated value using either the time series data or the histogram data based on a preset calculation model,
wherein
the histogram data includes parameters such as SOC (State Of Charge), temperature, current, and ΔDOD (Depth Of Discharge) of the secondary battery, and the computer causes the processor to calculate the SOH using each of the parameters and a product of two or more of the parameters.
